(19) United States
(12) Patent Application Publication
(10) Pub. No.: US 2024/0008322 A1
(43) Pub. Date: Jan. 4, 2024

(54) DISPLAY DEVICE

(71) Applicant: LG Display Co., Ltd., Seoul (KR)

(72) Inventor: So-Hee CHOI, Paju-si (KR)

(21) Appl. No.: 18/212,574

(22) Filed: Jun. 21, 2023

(30) Foreign Application Priority Data
Jun. 30, 2022 (KR) 10-2022-0080929

(51) Int. Cl. H10K 59/126; H10K 59/131

(52) U.S. Cl. CPC H10K 59/126; H10K 59/131

(57) ABSTRACT

A display device includes: a substrate having a display area and a non-display area; an emitting element electrically connected to a gate line and a data line, the emitting element including a first electrode, an emitting layer and a second electrode; a first thin film transistor (TFT) supplying a driving current to the emitting element according to a data voltage; a second TFT controlling an operation of the first TFT according to a gate voltage of the gate line; a third TFT controlling an operation of the first TFT by sensing a threshold voltage of the first TFT; a third electrode connecting the first drain electrode and the first electrode; and a fourth electrode on a same layer as the third electrode, overlapping the first semiconductor layer, the second semiconductor layer, or the third semiconductor layer.

### CROSS REFERENCE TO RELATED APPLICATIONS

The present application claims the priority benefit of Republic of Korea Patent Application No. 10-2022-0080929 filed in Republic of Korea on Jun. 30, 2022, which is incorporated herein by reference in its entirety.

### BACKGROUND

### Technical Field

The present disclosure relates to a display device, and more particularly, to a display device where reduction of a reliability is minimized or at least reduced by shielding a light from reaching a semiconductor layer.

### Discussion of the Related Art

As an information society progresses, a need for a display device displaying an image increases. Various display devices such as a liquid crystal display (LCD) device and an organic light emitting diode (OLED) display device have been utilized.

The display device used as a monitor of a computer or a display panel of a television and a mobile phone includes an organic light emitting diode (OLED) display device of an emissive type and a liquid crystal display (LCD) device of a non-emissive type.

Since the OLED display device does not use an additional light source and uses an emitting element of an emissive type, the OLED display device has been widely used due to its thin profile and excellent display quality. Specifically, since an emitting element is formed on a flexible substrate, the OLED display device may have various shapes, such as bending or folding and may be applied to various display applications.

An OLED display device having a new driving element part that prevents or at least reduces a leakage current in a static image has been required for a display device of a smart watch and a monitor having a lot of static images among various display applications. As a result, a technology that an oxide semiconductor layer is used as an active layer of a thin film transistor of a driving element part is being developed.

### SUMMARY

Accordingly, embodiments of the present disclosure are directed to a display device that substantially obviates one or more of problems due to the limitations and disadvantages of the related art.

An object of the present disclosure is to provide a display device where an influence on an oxide semiconductor layer of a thin film transistor of a driving element part is reduced by shielding a light emitted and transmitted from a subpixel and/or a light inputted from an exterior.

Another object of the present disclosure is to provide a display device where reliability is improved by preventing or at least reducing incident light from reaching semiconductor layers of a driving element part through penetration and/or reflection.

Additional features and advantages of the disclosure will be set forth in the description which follows, and in part will be apparent to those skilled in the art from the description or may be learned by practice of the disclosure. These and other advantages of the disclosure may be realized and attained by the structure particularly pointed out in, or derivable from, the written description, claims hereof, and the appended drawings.

Embodiments described herein relate to display devices that achieve the above-described advantages. In one embodiment, a display device includes: a substrate having a display area and a non-display area; an emitting element connected to a gate line and a data line crossing the gate line in the display area, the emitting element including a first electrode, an emitting layer and a second electrode; a first thin film transistor supplying a driving current to the emitting element according to a data voltage of the data line, the first thin film transistor including a first semiconductor layer, a first source electrode and a first drain electrode; a second thin film transistor controlling an operation of the first thin film transistor according to a gate voltage of the gate line, the second thin film transistor including a second semiconductor layer; a third thin film transistor controlling an operation of the first thin film transistor by sensing a threshold voltage of the first thin film transistor, the third thin film transistor including a third semiconductor layer; a third electrode connecting the first drain electrode and the first electrode; and a fourth electrode having a same layer as the third electrode, the fourth electrode overlapping the first semiconductor layer, the second semiconductor layer, or the third semiconductor layer.

In one embodiment, a display device includes a substrate, a thin film transistor on the substrate, a light emitting element on the thin film transistor, a third electrode between the thin film transistor and the light emitting element on a planarizing layer, and a fourth electrode also on the planarizing layer. The thin film transistor includes a semiconductor layer including oxide semiconductor, and a source electrode and a drain electrode above the semiconductor layer. The light emitting element includes a first electrode, an emitting layer, and a second electrode. The third electrode electrically connects the first electrode to one of the source electrode or drain electrode on the drain electrode of the thin film transistor. The fourth electrode overlaps the semiconductor layer in a first direction, and at least a portion of the fourth electrode is spaced apart from the third electrode.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view showing a display device according to a first embodiment of the present disclosure;

FIG. 2 is a plan view showing a display panel of a display device according to a first embodiment of the present disclosure;

FIG. 3 is a plan view showing a touch part of a display device according to an embodiment of the present disclosure;

FIG. 4 is a view showing a pixel circuit of a display device according to a first embodiment of the present disclosure;

FIG. 5 is a cross-sectional view taken along a line V-V′ of FIG. 1 according to an embodiment of the present disclosure;

FIG. 6 is a cross-sectional view showing a path of a light in a display device according to a first embodiment of the present disclosure; and

FIG. 7 is a cross-sectional view showing a path of a light in a display device according to a second embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

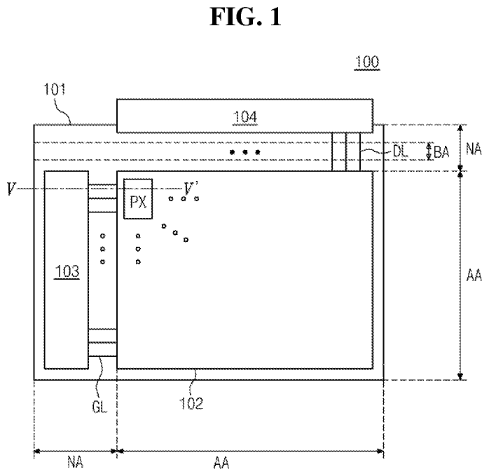

FIG. 1 is a plan view showing a display device according to a first embodiment of the present disclosure.

In FIG. 1, a display device 100 according to a first embodiment of the present disclosure may include a display panel 102, a gate driving unit 103 and a data driving unit 104 on a substrate 101. The display panel 102 may include a display area AA and a non-display area NA at periphery of the display area AA including the gate driving unit 103 and the data driving unit 104.

In some embodiments, the substrate 101 may include a glass or a plastics. The embodiments of the present disclosure is not limited thereto. In some embodiments, the substrate 101 may include a semiconductor material such as a wafer.

The substrate 101 may include a plastic material having flexibility. For example, the substrate 101 may have a single layer or a multiple layer including at least one of polyimide (PI), polyethylene terephthalate (PET), polyethylene naphthalate (PEN), polycarbonate (PC), polyethersulfone (PES), polyarylate (PAR), polysulfone (PSF) and cyclic-olefin copolymer (COC). The embodiments of the present disclosure are not limited thereto.

The display area AA may be a region where a plurality of subpixels PX are disposed and an image is displayed. Each of the plurality of subpixels PX may be an individual unit emitting a light. An emitting element and a driving circuit may be disposed in each of the plurality of subpixels PX. For example, a display element for displaying an image and a circuit element for driving the display element may be disposed in each of the plurality of subpixels PX. The display element may include an organic light emitting element when the display device 100 is an organic light emitting diode display device, and the display element may include a liquid crystal element when the display device 100 is a liquid crystal display device. The plurality of subpixels PX may include a red subpixel PX, a green subpixel PX, a blue subpixel PX and/or a white subpixel PX. The embodiments of the present disclosure are not limited thereto.

The non-display area NA may be a region where an image is not displayed. The non-display area NA may be a region where various lines and a driving integrated circuit for driving the plurality of subpixels PX in the display area AA are disposed. For example, at least one of a data driving unit 104 and a gate driving unit 103 may be disposed in the non-display area NA. The embodiments of the present disclosure are not limited thereto.

The non-display area NA may be a region surrounding the display area AA. For example, the non-display area NA may be a region extending from the display area AA or a region where the plurality of subpixels PX are not disposed. The embodiments of the present disclosure is not limited thereto. The non-display area NA where an image is not displayed may be a bezel region or may further include a bending region BA where the substrate 101 is bent. The embodiments of the present disclosure are not limited thereto.

The subpixel PX of the display area AA may include a thin film transistor (TFT). A semiconductor layer of the TFT may include a polycrystalline semiconductor material and/or an oxide semiconductor material. The embodiments of the present disclosure are not limited thereto.

The gate driving unit 103 in the non-display area NA may include a thin film transistor. A semiconductor layer of the gate driving unit 103 may include a polycrystalline semiconductor material. The embodiments of the present disclosure are not limited thereto.

The gate driving unit 103 may be formed directly on the substrate 101 and may have a complementary metal oxide semiconductor (C-MOS) of a TFT including a semiconductor layer of a polycrystalline semiconductor material and a TFT including a semiconductor layer of an oxide semiconductor material. As a result, an electron mobility in a channel region of a TFT increases, and a display device having a relatively high resolution and a relatively low power consumption is obtained.

A plurality of data lines DL and a plurality of gate lines GL may be disposed in the display area AA. For example, the plurality of data lines DL may be disposed in a row or a column, and the plurality of gate lines GL may be disposed in a column or a row. The subpixel PX may be disposed in a region defined by crossing of the data line DL and/or the gate line GL.

The gate driving unit 103 including a gate driving circuit (or a scan driving circuit) may be disposed in the non-display area NA. The gate driving circuit of the gate driving unit 103 may sequentially drive pixel rows of the display area AA by sequentially supplying a scan signal to the plurality of gate lines GL.

The gate driving circuit of the gate driving unit 103 may include a TFT having a polycrystalline semiconductor layer or a TFT having an oxide semiconductor layer. Alternatively, the gate driving circuit of the gate driving unit 103 may include a pair of a TFT having a polycrystalline semiconductor layer and a TFT having an oxide semiconductor layer. When the TFT in the non-display area NA and the TFT in the display area AA include the same semiconductor material, the TFT in the non-display area NA and the TFT in the display area AA may be simultaneously formed through the same process.

The gate driving circuit may include a shift register and a level shifter. The gate driving circuit may have a gate in panel (GIP) type to be disposed directly on the substrate 101. The gate driving unit 103 including the gate driving circuit may sequentially supply a scan signal having an ON voltage or an OFF voltage to the plurality of gate lines GL.

When a gate line GL is selected by the gate driving unit 103 including the gate driving circuit, the data driving circuit of the data driving unit 104 may convert an image data of a digital type into a data voltage of an analog type and may supply the data voltage to the plurality of data lines DL.

The plurality of gate lines GL may include a plurality of scan lines and a plurality of emission lines. The plurality of scan lines and the plurality of emission lines may transmit gate signals (a scan signal and an emission signal) to gate nodes of transistors (a scan transistor and an emission transistor).

The gate driving circuit of the gate driving unit 103 may include a scan driving circuit outputting the scan signal to the scan line of the plurality of gate lines GL and an emission driving circuit outputting the emission signal to the emission line of the plurality of gate lines GL.

The data line DL may be disposed to pass through the bending area BA and to be connected to a data pad.

The bending area BA may be a region where the substrate 101 is bent. The substrate 101 may be kept flat except for the bending area BA.

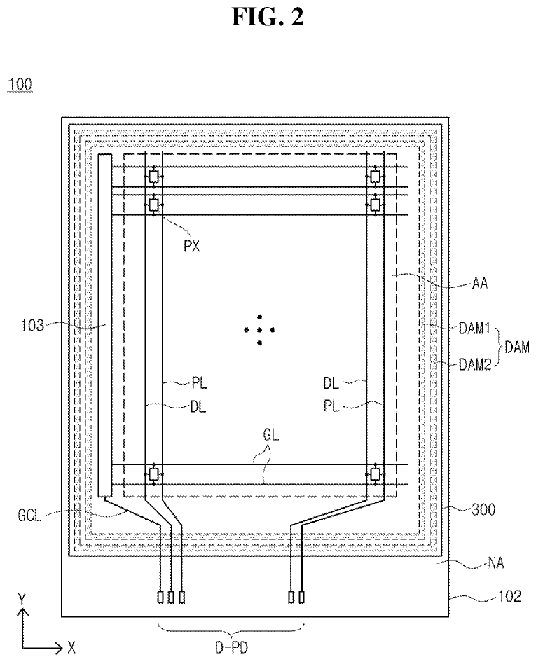

FIG. 2 is a plan view showing a display panel of a display device according to a first embodiment of the present disclosure.

In FIG. 2, a display device 100 may include a display panel 102 having a driving element part including a plurality of TFTs for displaying an image, an emitting element part including a plurality of emitting elements having emitting layers, an encapsulation part 300 encapsulating the emitting layers and a touch sensing part having a touch sensing function on the encapsulation part 300 with an organic buffer layer interposed therebetween. An end portion of the organic buffer layer having a relatively great thickness and an end portion of the encapsulation part 300 may be disposed as a stair shape to have an end profile of a stair shape. The display device 100 may further include an optically functional film such as a polarization film, an optically cleared adhesive (OCA), a cover substrate and a protection film on the touch sensing part.

The display panel 102 may include a driving element part having a plurality of pixel circuits in a display area AA and an emitting element part having a plurality of emitting elements in the display area AA.

A line part including a plurality of signal lines connected to the display area AA and a plurality of display pads D-PD for connection of display driving unit may be disposed in the non-display area NA of the display panel 102. The plurality of signal lines in the non-display area NA may include a link line and a power supply line PL connected to the plurality of signal lines GL and DL in the display area AA. The driving element part may include a lower pad of the plurality of display pads D-PD connected to an upper pad of the touch sensing part.

A gate driving unit 103 driving the plurality of gate lines GL in the display area AA may be disposed in one side portion or both side portions of the non-display area NA of the display panel 102. The gate driving unit 103 including a plurality of TFTs may be formed in the driving element part with a TFT array in the display area AA. The gate driving unit 103 may receive a plurality of control signals from the display driving unit through the plurality of signal lines GCL and the plurality of display pads D-PD in the non-display area NA.

The display driving unit may be mounted in the pad area where the plurality of display pads D-PD are disposed or may be mounted on a circuit film. The driving unit may be connected to the plurality of display pads D-PD through an anisotropic conductive film. The circuit film may include one of a chip on film (COF), a flexible printed circuit (FPC) and a flexible flat cable (FFC). The embodiments of the present disclosure are not limited thereto. The display driving unit may include a timing controlling unit, a gamma voltage generating unit and a data driving unit.

In some embodiments, the encapsulation part 300 on the display panel 102 may overlap an entire display area AA. In some embodiments, the encapsulation part 300 may further extend to the non-display area NA to overlap a dam layer (DAM) in the non-display area NA. The encapsulation part 300 may seal and protect the emitting element part of the display panel 102. The encapsulation part 300 may have a lamination structure including a plurality of inorganic encapsulating layers blocking penetration of a moisture and an oxygen and at least one organic encapsulating layer blocking injection or floating of particles. The encapsulation part 300 may have a structure where the organic encapsulating layer having a relatively great thickness to cover particles is disposed between the inorganic encapsulating layers having a relatively small thickness. The organic encapsulating layer may be referred to as a particle cover layer (PCL).

The dam layer DAM may be disposed in the non-display area NA and may prevent or at least reduce spillage or collapse of the organic encapsulating layer by accommodating an end portion of the organic encapsulating layer of the encapsulation part 300. For example, the dam layer DAM may include a plurality of dams DAM1 and DAM2 each having a closed loop shape surrounding a region including the display area AA and the gate driving unit 103 of the display panel 102.

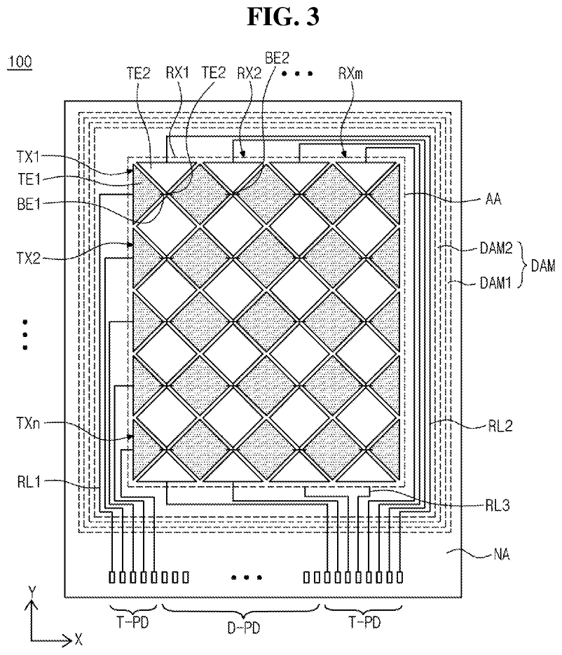

FIG. 3 is a plan view showing a touch part of a display device according to an embodiment of the present disclosure.

In FIG. 3, the touch sensing part on the encapsulation part 300 may have a capacitance type where a touch signal reflecting a capacitance change due to a touch of a user is provided to a touch driving unit. The touch sensing part may have a self-capacitance type where the touch signal reflecting the capacitance change of each touch electrode is independently provided to the touch driving unit or may have a mutual capacitance type where the touch signal reflecting the capacitance change between first and second touch electrodes is provided to the touch driving unit. The touch sensing part of a mutual capacitance type may be exemplarily illustrated hereinafter.

The touch sensing part may include a plurality of touch electrodes TE1 and TE2 constituting a touch sensor of a mutual capacitance type and a plurality of connecting electrodes BE1 and BE2 in the display area AA. The touch sensing part may further include a plurality of touch routing lines RL1, RL2 and RL3 and a plurality of touch pads T-PD in the non-display area NA. The upper pads of the plurality of display pads D-PD may have the same metallic material and the same layer as upper pads of the plurality of touch pads T-PD and may have the same metallic material and the same layer as the plurality of touch electrodes TE1 and TE2.

The touch sensing part may include a plurality of first touch electrode channels TX1 to TXn and a plurality of second touch electrode channels RX1 to RXm. The plurality of first touch electrode channels TX1 to TXn may be connected to the plurality of first touch electrodes TE1 disposed along a first direction (an X axis direction or a horizontal direction) in the display area AA and electrically connected to each other. The plurality of second touch electrode channels RX1 to RXm may be connected to the plurality of second touch electrodes TE2 disposed along a second direction (a Y axis direction or a vertical direction) in the display area AA and electrically connected to each other. The adjacent first and second touch electrodes TE1 and TE2 may constitute each touch sensor of a mutual capacitance type.

In each of the plurality of first touch electrode channels TXi (i=1, . . . , n), each of the plurality of first touch electrodes TE1 along the first direction X may be connected to the adjacent first touch electrode TE1 through a first connecting electrode BE1. In each of the plurality of second touch electrode channels RXi (i=1, . . . , m), each of the plurality of second touch electrodes TE2 along the second direction Y may be connected to the adjacent second touch electrode TE2 through a second connecting electrode BE2. The first touch electrode TE1 may be referred to as a transmitting electrode, and the second touch electrode TE2 may be referred to as a receiving electrode. The plurality of first touch electrode channels Tx1 to Txn may be referred to as a transmitting channel, and the plurality of second touch electrode channels Rx1 to Rxm may be referred to as a receiving channel or a readout channel. Each of the first and second touch electrodes TE1 and TE2 may have a lozenge shape. The embodiments of the present disclosure are not limited thereto.

The plurality of touch routing lines RL1, RL2 and RL3 and the plurality of touch pads T-PD may be disposed in the non-display area NA of the touch sensing part. The plurality of touch routing lines RL1, RL2 and RL3 may be connected to the plurality of touch electrode channels TX1 to TXn and RX1 to RXm in the display area AA. The plurality of touch pads T-PD may be connected to the plurality of touch routing lines RL1, RL2 and RL3. The plurality of touch routing lines RL1, RL2 and RL3 may overlap the encapsulation part 300 in the non-display area NA surrounding the display area AA. The touch driving unit may be mounted on a circuit film and may be connected to the plurality of touch pads T-PD in the non-display area NA through an anisotropic conductive film.

One end portion of each of the plurality of first touch electrode channels TX1 to TXn in the display area AA may be connected to the touch driving unit through the plurality of first touch routing lines RL1 and the plurality of touch pads T-PD in the non-display area NA. The plurality of first touch routing lines RL1 may be individually connected to the plurality of touch pads T-PD in a lower region of the non-display area NA through one of left and right regions of the non-display area NA and the lower region of the non-display area NA.

The touch driving unit may drive the plurality of first touch electrode channels TX1 to TXn and may receive a readout signal outputted from the plurality of second touch electrode channels RX1 to RXm. The touch driving unit may generate a touch sensing data using the readout signal. For example, the touch driving unit may generate a touch sensing signal reflecting whether a touch occurs or not by comparing the readout signals of the two adjacent channels through a differential amplifier and may convert the touch sensing signal into the touch sensing data of a digital type to output the touch sensing data to a touch controller. The touch controller may calculate a touch coordinate of a touch region based on the touch sensing data and may provide the touch coordinate to a host system.

The touch sensing part may be disposed over the encapsulation part 300 in the display area AA with an organic buffer layer having a thickness similar to the encapsulation part 300 interposed therebetween. As a result, a fabrication process may be simplified and a fabrication cost may be reduced as compared with a display device of an attaching type of a touch panel. Since a touch sensing function is improved by reducing a parasitic capacitance between the touch sensing part and the display panel 102, a reliability of the display device 100 may be improved.

Since the end portion of the organic buffer layer and the end portion of the encapsulation part 300 are disposed as a stair shape, the end portion of the organic buffer layer of the touch sensing part and the end portion of the encapsulation part 300 may have a cross-sectional profile of a stair shape. Each of the plurality of touch routing lines RL1, RL2 and RL3 may include a lower routing line along the end portion of the encapsulation part 300 and an upper routing line along the end portion of the organic buffer layer and connected to the lower routing line through a contact hole on the end portion of the encapsulation part 300. Since the plurality of touch routing lines RL1, RL2 and RL3 are stably formed in a region of the stair-shaped end portion of the organic buffer layer and the encapsulation part 300 without deterioration of an electric open, a yield and a reliability of the display device 100 may be improved.

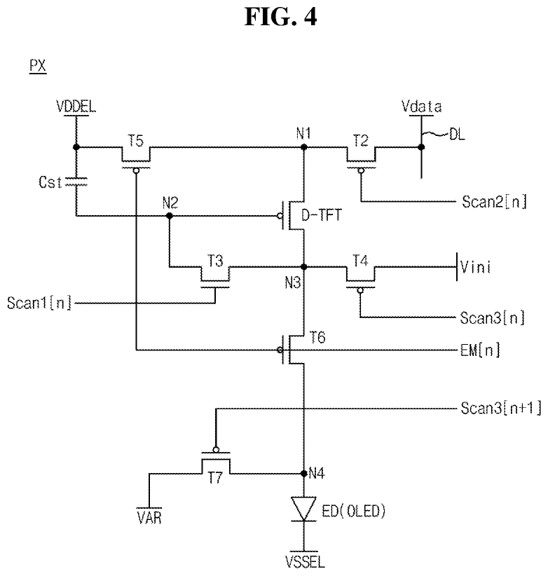

FIG. 4 is a view showing a pixel circuit of a display device according to a first embodiment of the present disclosure.

In FIG. 4, a pixel circuit may include seven thin film transistors (TFTs) and one storage capacitor Cst. For example, one of the seven TFTs may be a driving TFT D-TFT and the others of the seven TFTs may be switching TFTs T2 to T7 for an inner compensation.

In the pixel circuit, the driving TFT D-TFT and the switching TFT T3 adjacent to the driving TFT D-TFT may include a semiconductor layer of an oxide semiconductor material and at least one of the other switching TFTs T2 and T4 to T7 may include a semiconductor layer of a polycrystalline semiconductor material. The embodiments of the present disclosure are not limited thereto. Each TFT may have a positive (P) type or a negative (N) type.

The N type TFT (transistor) may be an oxide transistor having a semiconductor layer of an oxide semiconductor material. For example, the oxide TFT may include a semiconductor layer of an oxide semiconductor material such as indium oxide, gallium oxide, zinc oxide and indium gallium zinc oxide.

The P type TFT (transistor) may be a polycrystalline transistor having a semiconductor layer of a semiconductor material such as silicon. For example, the polycrystalline TFT may include a semiconductor layer of a low temperature polycrystalline silicon (LTPS) through a low temperature process.

The oxide transistor may have a relatively low leakage current as compared with the polycrystalline transistor.

A second TFT T2 may switch an electric connection between a first node N1 of the driving TFT D-TFT and the data line DL. The first node N1 of the driving TFT D-TFT may be one of a source electrode and a drain electrode of the driving TFT D-TFT. An operation timing of the second TFT T2 may be controlled according to a second scan signal Scan2(n). When the second scan signal Scan2(n) of a turn-on level voltage is applied to the second TFT T2, the data voltage Vdata is applied to the first node N1 of the driving TFT D-TFT.

A third TFT T3 may be electrically connected between the second node N2 and the third node N3 of the driving TFT D-TFT. An operation timing of the third TFT T3 may be controlled according to the first scan signal Scan1(n). A third node N3 of the driving TFT D-TFT may be the other one of the source electrode and the drain electrode of the driving TFT D-TFT.

The third TFT T3 may be an oxide transistor. Since the oxide transistor has a relatively low leakage current, a voltage level of the second node N2 of the driving TFT D-TFT may be kept relatively low. As a result, the subpixel PX may display an image based on the data voltage Vdata for displaying an image inputted during a previous frame even when the data voltage Vdata for displaying an image is not applied during each frame.

A fourth TFT T4 may switch an electric connection between the third node N3 of the driving TFT D-TFT and an initialization line. An operation timing of the fourth TFT T4 may be controlled according to a third scan signal Scan3(n). When the third scan signal Scan3(n) of a turn-on level voltage is applied to the fourth TFT T4, an initialization voltage Vini is applied to the third node N3 of the driving TFT D-TFT.

A fifth TFT T5 may switch an electric connection between the first node N1 of the driving TFT D-TFT and a high level line where the high level voltage VDDEL is applied. An operation timing of the fifth TFT T5 may be controlled according to an emission signal EM(n). When the emission signal EM(n) of a turn-on level voltage is applied to the fifth TFT T5, the high level voltage VDDEL may be applied to the first node N1 of the driving TFT D-TFT.

A sixth TFT T6 may switch an electric connection between the third node N3 of the driving TFT D-TFT and a first electrode of the emitting element ED. The sixth TFT T6 may include a fourth node N4 electrically connected to the first electrode of the emitting element ED. The fourth node N4 of the sixth TFT T6 may be a source electrode or a drain electrode of the sixth TFT T6. The first electrode of the emitting element ED may be an anode or a cathode. The emitting element ED having the first electrode of an anode may be exemplarily illustrated hereinafter.

An operation timing of the sixth TFT T6 may be controlled according to the emission signal EM(n). The emission signal EM(n) controlling the operation timing of the sixth TFT T6 may be the same as the emission signal EM(n) controlling the operation timing of the fifth TFT T5. The gate electrode of the sixth TFT T6 and the gate electrode of the fifth TFT T5 may be electrically connected to the single emission line transmitting the emission signal EM(n).

A seventh TFT T7 may switch an electric connection between the first electrode of the emitting element ED and a reset line transmitting a reset voltage VAR. When the first electrode of the emitting element ED is an anode, the reset voltage VAR may be an anode reset voltage.

An operation timing of the seventh TFT T7 may be controlled according to a third scan signal Scan3(n+1). The third scan signal Scan3(n+1) controlling the operation timing of the seventh TFT T7 may be the same as the third scan signal Scan3(n) controlling the operation timing of the fourth TFT T4 in the other subpixel PX.

For example, the third scan signal Scan3(n+1) may be applied to the seventh TFT T7 in the subpixel PX electrically connected to an nth gate line (n is an integer equal to or greater than 1). The third scan signal Scan3(n+1) may be applied to the fourth TFT T4 in the subpixel electrically connected to an (n+1)th gate line.

The storage capacitor Cst may apply a voltage corresponding to the data voltage Vdata to the gate electrode of the driving TFT D-TFT for one frame. The storage capacitor Cst may include a first terminal electrically connected to the second node N2 and a second terminal electrically connected to the high level line transmitting the high level voltage VDDEL. The second node N2 of the driving TFT D-TFT may be the gate electrode of the driving TFT D-TFT.

A first electrode of the emitting element ED or a light emitting diode OLED may be electrically connected to the fourth node N4 of the sixth TFT T6. A second electrode of the emitting element ED may be electrically connected to a low level line transmitting a low level voltage VSSEL. The first electrode of the emitting element ED may be an anode or a cathode, and the second electrode of the emitting element ED may be a cathode or an anode.

The high level line transmitting the high level voltage VDDEL and the low level line transmitting the low level voltage VSSEL may be a common line commonly connected to the plurality of subpixels PX in the display panel 102.

In the display device 100, the third TFT T3 may exemplarily have an N type, and the other TFTs may have a P type. The driving TFT D-TFT, the second TFT T2, the fourth TFT T4, the fifth TFT T5, the sixth TFT T6 and the seventh TFT T7 may have a P type, or at least one of the driving TFT D-TFT, the second TFT T2, the fourth TFT T4, the fifth TFT T5, the sixth TFT T6 and the seventh TFT T7 may have an N type.

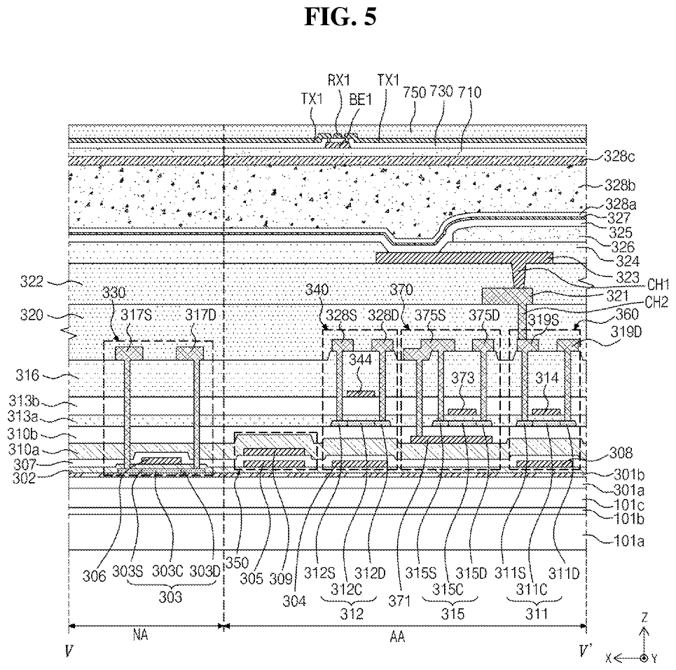

FIG. 5 is a cross-sectional view taken along a line V-V′ of FIG. 1.

In FIG. 5, the display device 100 according to a first embodiment of the present disclosure may include one driving TFT D-TFT (or a first TFT 370), a plurality of switching TFTs (or a second TFT 360), one sampling TFT (or a third TFT 340) and the storage capacitor Cst in the driving element part of the display area AA. The display device 100 may further include at least one switching TFT (or a fourth TFT 330) in the driving element part (or the gate driving unit 103) in the non-display area NA.

One subpixel PX may include the driving element part and the emitting element part electrically connected to each other on the substrate 101. The driving element part may be an array part for driving one subpixel where the driving TFT, the switching TFT (the sampling TFT) and the storage capacitor are disposed. The emitting element part may be an array part for emitting a light where the anode, the cathode and the emitting layer between the anode and cathode are disposed. The driving element part and the emitting element part may be insulated by planarizing layers 320 and 322.

The driving TFT D-TFT (or the first TFT 370) and the at least one switching TFT 340 (or the sampling TFT or the third TFT) may include a semiconductor layer of an oxide semiconductor material (or a semiconductor oxide material). Since the TFT having a semiconductor layer of an oxide semiconductor material has an excellent effect of blocking a leakage current, a power consumption is reduced and a fabrication cost is reduced as compared with the TFT having a semiconductor layer of a polycrystalline semiconductor material.

The substrate 101 may have a multiple layer where an organic layer and an inorganic layer are alternately disposed. For example, an organic layer 101a and 101c of polyimide (PI) and an inorganic layer 101b of silicon oxide (SiOx) may be alternately laminated to form the substrate 101.

The third layer 101b may be disposed between the first layer 101a and the second layer 101c. The third layer 101b may include silicon oxide (SiOx) or silicon nitride (SiNx). The embodiments of the present disclosure are not limited thereto. The third layer 101b may be an insulating layer or an interlayer.

A lower buffer layer 301 may be disposed on the substrate 101. The lower buffer layer 301 may block penetration of an external moisture. The lower buffer layer 301 may have a single layer or a multiple layer of silicon oxide (SiOx) or silicon nitride (SiNx). For example, to increase an effect of blocking an external moisture, the lower buffer layer 301 may include a first lower buffer layer 301a and a second lower buffer layer 301b.

The fourth TFT 330 may be disposed in the driving element part (or the gate driving unit 103) of the non-display area NA on the substrate 101. The fourth TFT 330 may include a fourth semiconductor layer 303 having a channel region where an electron or a hole is transmitted, a fourth gate electrode 306, a fourth source electrode 317S and a fourth drain electrode 317D. The fourth semiconductor layer 303 of the fourth TFT 330 may include a polycrystalline semiconductor material.

The fourth semiconductor layer 303 of a polycrystalline semiconductor material may include a fourth channel region 303C at a center of the fourth semiconductor layer 303 and a fourth source region 303S and a fourth drain region 303D at both sides of the fourth channel region 303C.

The fourth channel region 303C of an intrinsic polycrystalline semiconductor material may provide a path where an electron or a hole is transmitted.

The fourth source region 303S and the fourth drain region 303D may be a conductization region where an intrinsic polycrystalline semiconductor material is doped with an impurity of V or III group such as phosphorous (P) or boron (B).

The fourth gate electrode 306 overlaps the fourth channel region 303C of the fourth semiconductor layer 303. A first gate insulating layer 302 is disposed between the fourth gate electrode 306 and the fourth semiconductor layer 303.

The fourth TFT 340 has a top gate type where the fourth gate electrode 306 is disposed on the fourth semiconductor layer 303. Since a first capacitor electrode 305 and a light shielding layer (or a lower gate electrode) 304 and 308 having the same material as the fourth gate electrode 306 are formed through a single mask process, a fabrication is simplified.

The fourth gate electrode 306 may include a metallic material. For example, the fourth gate electrode 306 may have a single layer or a multiple layer including one of molybdenum (Mo), aluminum (Al), chromium (Cr), gold (Au), titanium (Ti), nickel (Ni), neodymium (Nd) and copper (Cu) or an alloy thereof. The embodiments of the present disclosure are not limited thereto.

A first interlayer insulating layer 307 is disposed on the fourth gate electrode 306. The first interlayer insulating layer 307 may include silicon nitride (SiNx). For example, the first interlayer insulating layer 307 of silicon nitride (SiNx) may include hydrogen. After the fourth semiconductor layer 303 is formed and the first interlayer insulating layer 307 is formed on the fourth semiconductor layer 303, a heat treatment is performed. During the heat treatment, hydrogen in the first interlayer insulating layer 307 may be diffused into the fourth source region 303S and the fourth drain region 303D to increase conductivity of the polycrystalline semiconductor material and stabilize the polycrystalline semiconductor material. The heat treatment may be referred to as a hydrogenation process.

In the fourth TFT 330, an upper buffer layer 310, a second gate insulating layer 313a, a third gate insulating layer 313b and a second interlayer insulating layer 316 may be further disposed on the first interlayer insulating layer 307. The fourth source electrode 317S and the fourth drain electrode 317D may be disposed on the second interlayer insulating layer 316. The fourth source electrode 317S and the fourth drain electrode 317D may be connected to the fourth source region 303S and the fourth drain region 303D, respectively.

The upper buffer layer 310 may separate the fourth semiconductor layer 303 of a polycrystalline semiconductor material in the non-display area NA and the semiconductor layer 311, 312 and 315 of an oxide semiconductor material of the TFTs in the display area AA and may provide a base where the semiconductor layer 311, 312 and 315 of an oxide semiconductor material of the TFTs in the display area AA are disposed.

The second interlayer insulating layer 316 or the third gate insulating layer 313b is an interlayer insulating layer covering the first upper gate electrode 373 of the first TFT 370, the second upper gate electrode 314 of the second TFT 360 and the third upper gate electrode 344 of the third TFT 340. Since the second interlayer insulating layer 316 or the third gate insulating layer 313b is disposed on the first semiconductor layer 315, the second semiconductor layer 311 and the third semiconductor layer 312 of an oxide semiconductor material, the second interlayer insulating layer 316 or the third gate insulating layer 313b may include an inorganic material.

The fourth source electrode 317S and the fourth drain electrode 317D may have a single layer or a multiple layer including one of molybdenum (Mo), aluminum (Al), chromium (Cr), gold (Au), titanium (Ti), nickel (Ni), neodymium (Nd) and copper (Cu) or an alloy thereof. The embodiments of the present disclosure are not limited thereto.

In FIG. 5, the first TFT 370, the second TFT 360, the third TFT 340 and the storage capacitor 350 may be disposed in the driving element part of the display area AA on the substrate 101.

The first TFT 370 (the driving TFT D-TFT) is disposed on the upper buffer layer 310. The first TFT 370 may provide a driving current to the emitting element ED according to the data voltage of the data line DL. The first TFT 370 may include the first semiconductor layer 315 of an oxide semiconductor material or a polycrystalline semiconductor material.

Since the TFT having a semiconductor layer of a polycrystalline semiconductor material has a leakage current in an OFF state, the TFT having a semiconductor layer of a polycrystalline semiconductor material may have a great power consumption as compared with the TFT having a semiconductor layer of an oxide semiconductor material. In the TFT having a semiconductor layer of an oxide semiconductor material, the semiconductor layer may deteriorate due to incident light. In the display device 100 according to a first embodiment of the present disclosure, since the semiconductor layer of the TFT in the display area AA is formed of an oxide semiconductor material, a leakage current and a power consumption are reduced. In addition, deterioration of the semiconductor layer caused by incident light is reduced.

The first semiconductor layer 315 of the first TFT 370 may include an oxide semiconductor material. The first TFT 370 includes a first semiconductor layer 315 of an oxide semiconductor material, a second gate insulating layer 313a covering the first semiconductor layer 315, a first upper gate electrode 373 on the second gate insulating layer 313a and overlapping the first semiconductor layer 315, a third gate insulating layer 313b covering the first upper gate electrode 373, a second interlayer insulating layer 316 on the third gate insulating layer 313b and a first source electrode 375S and a first drain electrode 375D on the second interlayer insulating layer 316.

The first TFT 370 further includes a first lower gate electrode 371 (a first light shielding layer) between a first upper buffer layer 310a and a second upper buffer layer 310b and overlapping the first semiconductor layer 315. The first lower gate electrode 371 may be interposed in the upper buffer layer 310. For example, the first lower gate electrode 371 may be disposed on the first upper buffer layer 310a over the first interlayer insulating layer 307, and a second upper buffer layer 310b may be disposed on the first lower gate electrode 371 over the second upper buffer layer 310b. For example, the upper buffer layer 310 may include the first upper buffer layer 310a and the second upper buffer layer 310b. The embodiments of the present disclosure are not limited thereto.

The first upper buffer layer 310a may include silicon oxide (SiOx). Since the first upper buffer layer 310a is formed of silicon oxide (SiOx) without hydrogen, the first upper buffer layer 310a may be used as a base for the first TFT 370 having the first semiconductor layer 315 of an oxide semiconductor material.

The second upper buffer layer 310b may include silicon nitride (SiNx) having an excellent capturing ability of hydrogen. The second upper buffer layer 310b may wrap a top surface and a side surface of the first lower gate electrode 371 to seal the first lower gate electrode 371 completely.

Silicon nitride (SiNx) has an excellent capturing ability of hydrogen as compared with silicon oxide (SiOx). The first interlayer insulating layer 307 including hydrogen is disposed under the upper buffer layer 310. The hydrogen generated during the hydrogenation process of the fourth TFT 330 having the fourth semiconductor layer 303 of a polycrystalline semiconductor material may pass through the upper buffer layer 310 to reduce a reliability of the semiconductor layer of an oxide semiconductor material on the upper buffer layer 310. For example, when the hydrogen penetrates the semiconductor layer of an oxide semiconductor material, the corresponding TFTs may have different threshold voltages or different conductivities according to a position. Specifically, since the driving TFT directly contributes operation of the emitting element, it is important to obtain a reliability of the driving TFT.

In the display device 100 according to a first embodiment of the present disclosure, since the second upper buffer layer 310b completely covering the first lower gate electrode 371 is disposed on the first upper buffer layer 310a, deterioration of a reliability of the first TFT 370 due to hydrogen may be prevented or at least reduced.

The first lower gate electrode 371 of the first TFT 370 may include a metallic material such as titanium (Ti) having an excellent capturing ability of hydrogen. For example, the first lower gate electrode 371 of the first TFT 370 may have a single layer of titanium (Ti) or an alloy of molybdenum (Mo) and titanium (Ti) or a double layer of molybdenum (Mo) and titanium (Ti). The embodiments of the present disclosure are not limited thereto.

Titanium (Ti) may capture hydrogen diffused in the upper buffer layer 310 to prevent or at least reduce a likelihood of hydrogen from reaching the first semiconductor layer 315. In the first TFT 370, the first lower gate electrode 371 includes a metallic material such as titanium (Ti) having a capturing ability of hydrogen, and the second upper buffer layer 310b wrapping the first lower gate electrode 371 includes silicon nitride (SiNx) having a capturing ability of hydrogen. As a result, deterioration of a reliability of the semiconductor layer of an oxide semiconductor material due to hydrogen may be prevented or at least reduced.

The second upper buffer layer 310b including silicon nitride (SiNx) may be formed on a portion of the first upper buffer layer 310a to selectively cover the first lower gate electrode 371 instead of the entire display area AA similar to the first upper buffer layer 310a. For example, the second upper buffer layer 310b may include a different material from the first upper buffer layer 310a. When the second upper buffer layer 310b is disposed on the entire display area AA, the second upper buffer layer 310b may be detached from the first upper buffer layer 310a. To prevent or at least reduce the detachment of the second upper buffer layer 310b, the second upper buffer layer 310b may be selectively disposed on a portion corresponding to the first lower gate electrode 371.

The first lower gate electrode 371 and the second upper buffer layer 310b may be disposed directly under the first semiconductor layer 315 to overlap the first semiconductor layer 315. Further, the first lower gate electrode 371 and the second upper buffer layer 310b may have an area greater than an area of the first semiconductor layer 315 to completely overlap the first semiconductor layer 315.

The first source electrode 375S of the first TFT 370 may be electrically connected to the first lower gate electrode 371. Since an effective voltage applied to a first channel region 315C of the first semiconductor layer 315 is inversely proportional to a parasitic capacitance Cbuf between the first semiconductor layer 315 and the first lower gate electrode 371, the effective voltage applied to the first semiconductor layer 315 may be adjusted by the parasitic capacitance Cbuf. For example, when the first lower gate electrode 371 is disposed adjacent to the first semiconductor layer 315 to have a relatively great parasitic capacitance, a real current flowing through the first semiconductor layer 315 may be reduced and a control range of the first TFT 370 according to a voltage applied to the first upper gate electrode 373 may be enlarged. As a result, the emitting element may be precisely adjusted even in a relatively low gray level, and a problem of a stain may be solved.

In FIG. 5, the driving element part of the display area AA may include the storage capacitor (Cst) 350. The storage capacitor 350 stores the data voltage of the data line DL and provides the data voltage to the emitting element ED.

The storage capacitor 350 includes two electrodes and a dielectric layer between the two electrodes. The storage capacitor 350 may include a first capacitor electrode 305 having the same material and the same layer as the fourth gate electrode 306 and a second capacitor electrode 309 having the same material and the same layer as the first lower gate electrode 371. The first interlayer insulating layer 307 may be disposed between the first capacitor electrode 305 and the second capacitor electrode 309. The second capacitor electrode 309 of the storage capacitor 350 may be electrically connected to the first source electrode 375S.

In FIG. 5, the driving element part of the display area AA may include a plurality of second TFTs (switching TFTs) 360. The plurality of second TFTs 360 may control an operation of the first TFT 370 according to the gate voltage of the gate line GL.

The second TFT 360 may include a second semiconductor layer 311 of an oxide semiconductor material on the upper buffer layer 310, a second gate insulating layer 313a covering the second semiconductor layer 311, a second upper gate electrode 314 overlapping the second semiconductor layer 311 on the second gate insulating layer 313a, a third gate insulating layer 313b covering the second upper gate electrode 314, a second interlayer insulating layer 316 on the third gate insulating layer 313b and a second source electrode 319S and a second drain electrode 319D on the second interlayer insulating layer 316.

The second TFT 360 may further include a second lower gate electrode (or a second light shielding layer) 308 covering the second semiconductor layer 311 under the upper buffer layer 310. For example, the second lower gate electrode 308 may include the same material as the fourth gate electrode 306 and may be disposed on the first gate insulating layer 302. The second lower gate electrode 308 may be electrically connected to the second upper gate electrode 314 to constitute a dual gate (a double gate). Since the second TFT 360 has a dual gate structure, a current flowing through the second channel region 311C of the second semiconductor layer 311 may be precisely adjusted. Further, a display device of a relatively high resolution may be obtained by disposing the second TFT 360 in a smaller region.

The second semiconductor layer 311 is formed of an oxide semiconductor material and includes an intrinsic second channel region 311C without an impurity and a second source region 311S and a second drain electrode 311D doped with an impurity.

The distance between the second semiconductor layer 311 and the second lower gate electrode 308 may be greater than the distance between the first semiconductor layer 315 and the first lower gate electrode 371. Each TFT may have a different necessity of a precise control due to a dual gate according to its inherent function. For example, since a ratio of a change amount of a current of the emitting element OLED with respect to a change amount of a threshold voltage of the first TFT 370 is greater than a ratio of a change amount of a current of the emitting element OLED with respect to a change amount of a threshold voltage of the second TFT 360, the first TFT 370 may have a greater necessity of a precise control than the second TFT 360. For a precise control of a current amount of an emitting element, the distance between the first semiconductor layer 315 and the first lower gate electrode 371 is determined to be smaller than the distance between the second semiconductor layer 311 and the second lower gate electrode 308.

The second source electrode 319S and the second drain electrode 319D may have a single layer or a multiple layer including one of molybdenum (Mo), aluminum (Al), chromium (Cr), gold (Au), titanium (Ti), nickel (Ni), neodymium (Nd) and copper (Cu) or an alloy thereof similar to the fourth source electrode 317S and the fourth drain electrode 317D. The embodiments of the present disclosure are not limited thereto.

Since the second source electrode 319S and the second drain electrode 319D are formed on the second interlayer insulating layer 316 simultaneously with the fourth source electrode 317S and the fourth drain electrode 317D, a number of mask processes is reduced.

In FIG. 5, the driving element part of the display area AA may include a third TFT (a sampling TFT) 340. The third TFT 340 may control an operation of the first TFT 370 by sensing a threshold voltage of the first TFT 370 and compensating a change of the threshold voltage.

The third TFT 340 may include a third semiconductor layer 312 of an oxide semiconductor material on the upper buffer layer 310, a second gate insulating layer 313a covering the third semiconductor layer 312, a third gate insulating layer 313b covering the second gate insulating layer 313a, a third upper gate electrode 344 overlapping the third semiconductor layer 312 on the third gate insulating layer 313b, a second interlayer insulating layer 316 covering the third upper gate electrode 344 and a third source electrode 328S and a third drain electrode 328D on the second interlayer insulating layer 316.

The third TFT 340 may further include a third lower gate electrode (or a third light shielding layer) 304 overlapping the third semiconductor layer 312 under the upper buffer layer 310. For example, the third lower gate electrode 304 may include the same material as the fourth gate electrode 306 and may be disposed on the first gate insulating layer 302. The third lower gate electrode 304 may be electrically connected to the third upper gate electrode 344 to constitute a dual gate. Since the third TFT 340 has a dual gate structure, a current flowing through the third channel region 312C of the third semiconductor layer 312 may be precisely adjusted. Further, a display device of a relatively high resolution may be obtained by disposing the third TFT 340 in a smaller region.

The third semiconductor layer 312 is formed of an oxide semiconductor material and includes an intrinsic third channel region 312C without an impurity and a third source region 312S and a third drain electrode 312D doped with an impurity.

The distance between the third semiconductor layer 312 and the third lower gate electrode 304 may be greater than the distance between the first semiconductor layer 315 and the first lower gate electrode 371. Each TFT may have a different necessity of a precise control due to a dual gate according to its inherent function. For example, since a ratio of a change amount of a current of the emitting element OLED with respect to a change amount of a threshold voltage of the first TFT 370 is greater than a ratio of a change amount of a current of the emitting element OLED with respect to a change amount of a threshold voltage of the third TFT 340, the first TFT 370 may have a greater necessity of a precise control than the third TFT 340. For a precise control of a current amount of an emitting element, the distance between the first semiconductor layer 315 and the first lower gate electrode 371 is determined to be smaller than the distance between the third semiconductor layer 312 and the third lower gate electrode 304.

Similarly, a distance between the third semiconductor layer 312 and the third upper gate electrode 344 may be greater than a distance between the first semiconductor layer 315 and the first upper gate electrode 373 or a distance between the second semiconductor layer 311 and the second upper gate electrode 314. For example, since ratios of the change amount of the current of the emitting element OLED with respect to the change amount of the threshold voltage of the first, second and third TFTs 370, 360 and 340 are different from each other, a dual gate structure may be applied to the first, second and third TFTs 370, 360 and 340 for a more precise control of the current of the emitting element OLED. The distance between the first semiconductor layer 315 and the first upper gate electrode 373 of the first TFT 370 and the distance between the second semiconductor layer 311 and the second upper gate electrode 314 of the second TFT 360 may be determined to be smaller than the distance between the third semiconductor layer 312 and the third upper gate electrode 344 of the third TFT 340.

The third source electrode 328S and the third drain electrode 328D may have a single layer or a multiple layer including one of molybdenum (Mo), aluminum (Al), chromium (Cr), gold (Au), titanium (Ti), nickel (Ni), neodymium (Nd) and copper (Cu) or an alloy thereof similar to the fourth source electrode 317S and the fourth drain electrode 317D. The embodiments of the present disclosure are not limited thereto.

Since the third source electrode 328S and the third drain electrode 328D are formed on the second interlayer insulating layer 316 simultaneously with the fourth source electrode 317S and the fourth drain electrode 317D, a number of mask processes is reduced.

The third upper gate electrode 344 may be disposed on the second gate insulating layer 313a similar to the first upper gate electrode 373 or the second upper gate electrode 314. The embodiments of the present disclosure are not limited thereto. For example, the third upper gate electrode 344 may be disposed on the third gate insulating layer 313b, instead of the second gate insulating layer 313a.

Since an effective voltage applied to the third channel region 312C of the third semiconductor layer 312 is inversely proportional to a parasitic capacitance Cgi between the third semiconductor layer 312 and the third upper gate electrode 344, the effective voltage applied to the third semiconductor layer 312 may be controlled by adjusting the distance between the third semiconductor layer 312 and the third upper gate electrode 344.

The first upper gate electrode 373 of the first TFT 370, the second upper gate electrode 314 of the second TFT 360 and the third upper gate electrode 344 of the third TFT 340 in the display area AA may have a multiple layer including a lower layer of titanium (Ti) and an upper layer of a different metallic material such as molybdenum (Mo).

When the first upper gate electrode 373, the second upper gate electrode 314 and the third upper gate electrode 344 have a multiple metallic layer including titanium (Ti), the multiple layer may block hydrogen from an upper portion of the first TFT 370, the second TFT 360 and the third TFT 340 to protect the first semiconductor layer 315, the second semiconductor layer 311 and the third semiconductor layer 312.

Since the driving element part of the display device 100 includes the plurality of TFTs having different semiconductor layers, a plurality of layers are required and a plurality of masks are used in the fabrication process. To reduce a number of masks, layers of the plurality of TFTs may be simultaneously formed.

For example, the fourth gate electrode 306, the first capacitor electrode 305, the third lower gate electrode 304 and the second lower gate electrode 308 may have the same material and the same layer as each other. The second capacitor electrode 309 and the first lower gate electrode 371 may have the same material and the same layer as each other. The third semiconductor layer 312, the first semiconductor layer 315 and the second semiconductor layer 311 may have the same material and the same layer as each other and may be formed through the same conductization process as each other. The third upper gate electrode 344, the first upper gate electrode 373 and the second upper gate electrode 314 may have the same material and the same layer as each other. The fourth source electrode 317S, the fourth drain electrode 317D, the third source electrode 328S, the third drain electrode 328D, the first source electrode 375S, the first drain electrode 375D, the second source electrode 319S and the second drain electrode 319D may have the same material and the same layer as each other and may have a multiple layer including at least two layers.

In FIG. 5, to planarize a step difference due to a height difference of various layers, a first planarizing layer 320 and a second planarizing layer 322 may be sequentially disposed on the driving element part. The first planarizing layer 320 and the second planarizing layer 322 may have an organic layer including polyimide or acrylic resin.

In FIG. 5, an emitting element part (a light emitting diode) may be disposed on the second planarizing layer 322. The emitting element part may include a first electrode (an anode) 323, a second electrode (a cathode) 327 and an emitting layer 325. The first electrode 323 may be disposed in each subpixel PX, and the emitting layer 325 and the second electrode 327 may be disposed in the entire display area AA.

The emitting element part is connected to the driving element part through a third electrode (a connection electrode) 321 on the first planarizing layer 320. For example, the first electrode 323 of the emitting element part and may be connected to the first drain electrode 375D of the first TFT 370 or the second source electrode 319S of the second TFT 360 of the driving element part through the third electrode 321.

The first electrode 323 may be connected to the third electrode 321 through a first contact hole CH1 in the second planarizing layer 322. The third electrode 321 may be connected to the first drain electrode 375D through a second contact hole CH2 in the first planarizing layer 320.

The first electrode 323 may have a multiple layer of a transparent conductive layer and an opaque conductive layer having a relatively high reflectance. The transparent conductive layer may include a material having a relatively high work function such as indium tin oxide (ITO) and indium zinc oxide (IZO). The opaque conductive layer may have a single layer or a multiple layer of aluminum (Al), silver (Ag), copper (Cu), lead (Pb), molybdenum (Mo), titanium (Ti) and an alloy thereof. For example, the first electrode 323 may have a structure where the transparent conductive layer, the opaque conductive layer and the transparent conductive layer are sequentially disposed or a structure where the transparent conductive layer and the opaque conductive layer are sequentially disposed.

The emitting layer 325 may have a hole relating layer, an emitting material layer and an electron relating layer sequentially or reversely sequentially disposed on the first electrode 323. The emitting layer 325 may be disposed as one body in the entire display area AA.

A bank layer 324 may be referred to as a pixel defining layer exposing the first electrode 323 in each subpixel PX. The bank layer 324 may include an opaque material having a black color to prevent or at least reduce a light interference between the adjacent subpixels PX. For example, the bank layer 324 may include a light shielding material having at least one of a color pigment, an organic black and a carbon. A spacer 326 may be disposed on the bank layer 324.

The spacer 326 may minimize or at least reduce breakage of the display device 1000 due to an external impact by buffering a space between the substrate 101 having the emitting element and an upper substrate. The spacer 326 may include the same material as the bank layer 324 and may be simultaneously formed with the bank layer 324. The embodiments of the present disclosure are not limited thereto.

The second electrode 327 may face into the first electrode 323 and the emitting layer 325 may be interposed between the first electrode 323 and the second electrode 327. The second electrode 327 may be disposed on a top surface and a side surface of the emitting layer 325. The second electrode 327 may be disposed as one body in the entire display area AA. When the second electrode 327 is applied to a top emission type OLED display device, the second electrode 327 may include a transparent conductive material such as indium tin oxide (ITO) and indium zinc oxide (IZO).

In FIG. 5, an encapsulation part 328 preventing or at least reducing penetration of a moisture may be disposed on the second electrode 327. The encapsulation part 328 may include a first encapsulating layer 328a, a second encapsulating layer 328b and a third encapsulating layer 328c sequentially disposed on the second electrode 327.

The first encapsulating layer 328a and the third encapsulating layer 328c of the encapsulation part 328 may include an inorganic material such as silicon oxide (SiOx). The second encapsulating layer 328b of the encapsulation part 328 may include an organic material such as acrylic resin, epoxy resin, phenolic resin, polyamide resin and polyimide resin.

In FIG. 5, a touch part (a touch sensor part) may be disposed on the encapsulation part 328. The touch part may include a touch buffer layer 710, a touch insulating layer 730 and a touch protecting layer 750 and may have a plurality of touch electrodes TE and a plurality of connecting electrodes BE. The plurality of touch electrodes TE may include a plurality of first touch electrode channels TX1 to TXn each having a plurality of first touch electrodes TE1 disposed along a first direction (an X axis direction, a horizontal direction) and connected to each other and a plurality of second touch electrode channels RX1 to RXm each having a plurality of second touch electrodes TE2 disposed along a second direction (a Y axis direction, a vertical direction) and connected to each other. The plurality of touch electrodes TE and the plurality of connecting electrodes BE may the same layer or the different layer using the touch insulating layer 730 between the touch buffer layer 710 and the touch protecting layer 750.

In the display device 100 according to a first embodiment of the present disclosure, a color filter layer may be disposed on the touch part or between the touch part and the encapsulation part 328. To increase a purity of a light emitted from the emitting element ED in each subpixel PX, the color filter layer may be disposed on the touch part or between the touch part and the encapsulation part 328.

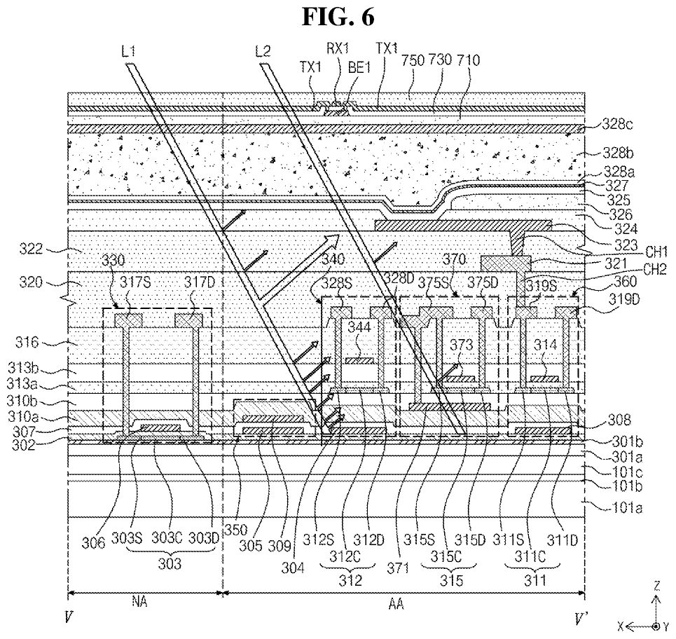

FIG. 6 is a cross-sectional view showing a path of a light in a display device according to a first embodiment of the present disclosure. FIG. 6 may correspond to a line V-V′ of FIG. 1 and illustration on a part of FIG. 6 the same as that of FIG. 5 may be omitted.

In FIG. 6, a first light L1 and a second light L2 may be inputted into an interior of the display device 100. The first light L1 and the second light L2 may be incident light from an exterior to an interior of the display device 100 or may be a light emitted and transmitted from the subpixel PX of the display device 100. The embodiments of the present disclosure are not limited thereto.

In a TFT having a semiconductor layer of an oxide semiconductor material, the semiconductor layer may deteriorate due to incident light to the semiconductor layer. Although a TFT having a semiconductor layer of an oxide semiconductor material has an excellent leakage current property as compared with a TFT having a semiconductor layer of a polycrystalline semiconductor material, a threshold voltage may be changed due to deterioration by a light and a leakage current property may be changed.

The light may have a path from a front surface of the display device 100 and a path from a rear surface of the display device 100. While the light passes through the planarizing layers 320 and 322, the interlayer insulating layers 307 and 316, the buffer layers 301 and 310 and the gate insulating layers 302 and 313, a part of the light may be transmitted through interface surfaces and the other part of the light may be reflected on the interface surfaces. The other part of the light reflected on the interface surfaces may be repeatedly re-reflected to influence the semiconductor layers of each TFT.

The light passing through the substrate 101 of the display device 100 may influence the semiconductor layer of each TFT. The lower gate electrode of each TFT may function as a light shielding layer. Since an area of the lower gate electrode is greater than an area of the semiconductor layer, the light passing through the substrate 101 may be effectively blocked by the lower gate electrode.

In FIG. 6, the second light L2 directly falls on the first semiconductor layer 315 of the first TFT 370. The second light L2 directly falls on the first semiconductor layer 315 may influence a property of the first TFT 370.

The first light L1 is not directly incident to the semiconductor layer of each TFT. While the first light L1 passes through the touch part, the encapsulation part 328, the planarizing layers 320 and 322, the interlayer insulating layers 307 and 316, the buffer layers 301 and 310 and the gate insulating layers 302 and 313 of the display device 100, a part of the first light L1 may be transmitted through each interface surface and the other part of the first light L1 may be reflected on each interface surface. The other part of the first light L1 reflected on each interface surface may be repeatedly re-reflected to be incident to the semiconductor layer. For example, an amount of the other part of the first light L1 may be reduced due to repetition of the re-reflection.

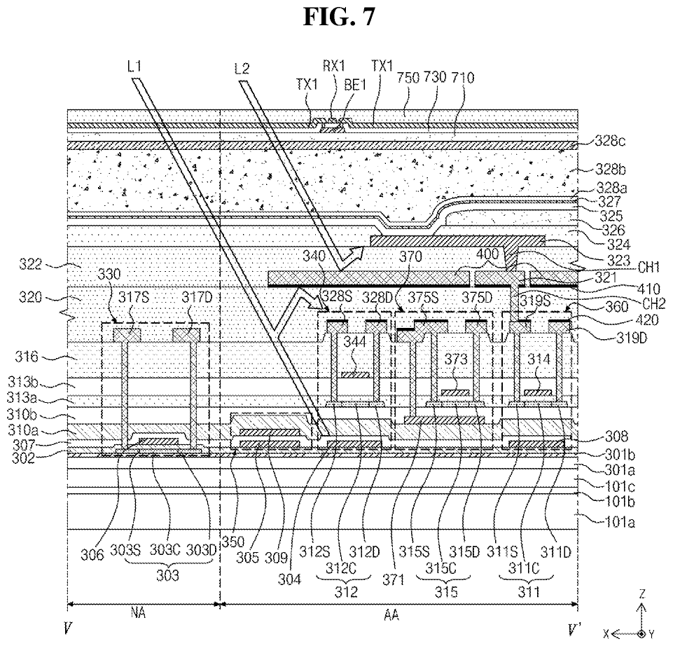

FIG. 7 is a cross-sectional view showing a path of a light in a display device according to a second embodiment of the present disclosure. FIG. 7 may correspond to a line V-V′ of FIG. 1 and illustration on a part of FIG. 7 the same as that of FIG. 5 may be omitted.

In FIG. 7, a display device according to a second embodiment of the present disclosure includes the third electrode (or a connecting electrode) 321 on the first planarizing layer 320. The third electrode 321 connects the first electrode 323 of the emitting element with the first drain electrode 375D of the first TFT 370 or the second source electrode 319S of the second TFT 360 of the driving element part.

A fourth electrode (or a light shielding electrode) 400 may be disposed between the first planarizing layer 320 and the second planarizing layer 322. The fourth electrode 400 may be disposed to be separated from the third electrode 321 or may be disposed in the entire display area AA except for a region where the third electrode 321 is disposed. The third electrode 321 and the fourth electrode 400 may have a multiple layer including at least two layers.

In FIG. 7, the second light L2 directly incident to the semiconductor layer of each TFT may be blocked by the fourth electrode 400. For example, the second light L2 incident from an exterior of the display device 100 toward the semiconductor layer may be reflected by the fourth electrode 400 and a path of the second light L2 toward the semiconductor layer may be blocked. A part of the second light L2 reflected by the fourth electrode 400 may be emitted to an exterior due to the polarizing plate or the color filter layer in the upper portion of the display device 100, and the other part of the second light L2 reflected by the fourth electrode 400 may be attenuated due to a total reflection. The embodiments of the present disclosure are not limited thereto.

The first light L1 is not directly incident to the semiconductor layer of each TFT. While the first light L1 passes through the touch part, the encapsulation part 328, the planarizing layers 320 and 322, the interlayer insulating layers 307 and 316, the buffer layers 301 and 310 and the gate insulating layers 302 and 313 of the display device 100, a part of the first light L1 may be transmitted through each interface surface and the other part of the first light L1 may be reflected on each interface surface. The other part of the first light L1 reflected on each interface surface may be repeatedly re-reflected to be incident to the semiconductor layer.

In FIG. 7, the fourth electrode 400 between the first planarizing layer 320 and the second planarizing layer 322 may be disposed to be separated from the third electrode 321. In some embodiments, the fourth electrode 400 and the third electrode 321 are on a same planarizing layer. In some embodiments, the fourth electrode 400 surrounds the third electrode 321. In some embodiments, the fourth electrode 400 may be disposed in the entire display area AA except for a region where the third electrode 321 is disposed or a gap between the third electrode 321 and the fourth electrode 400. In some embodiments, the substrate 101 includes a pixel area. The pixel area includes multiple thin film transistors (e.g., the first thin film transistor 370, the second thin film transistor 360, and/or the third thin film transistor 340). Each of the multiple thin film transistors includes a semiconductor layer. The fourth electrode 400 extends across to overlap the semiconductor layers of the multiple thin film transistors. The fourth electrode 400 is configured to block at least a portion of light incident to the fourth electrode from reaching a semiconductor layer of a thin film transistor, e.g., the first semiconductor layer 315 of the first thin film transistor 370, the second semiconductor layer 311 of the second thin film transistor 360, and/or the third semiconductor layer 312 of the third thin film transistor 340. For example, since the fourth electrode 400 is disposed in the entire driving element part, an amount of the first light L1 incident to the driving element part may be greatly reduced.

The first light L1 through the non-display area NA may be incident to the driving element part, and a part of the first light L1 may be transmitted through each interface surface and the other part of the first light L1 may be reflected on each interface surface. For example, the other part of the first light L1 may be reflected on the interface between the first planarizing layer 320 and the second interlayer insulating layer 316 to be emitted to the exterior of the display device 100, and the reflected first light L1 may be reflected on a bottom surface of the fourth electrode 400 or a bottom surface of the third electrode 321 to be incident to the semiconductor layer of each TFT.

To prevent or at least reduce deterioration of the semiconductor layer due to the reflected first light L1, the bottom surface (a bottom layer) of the fourth electrode 400 and the bottom surface (a bottom layer) of the third electrode 321 may be formed to include a first low reflection material layer 410 having at least one layer. The first low reflection material layer 410 may reduce an amount of the reflected light by irregularly or totally reflecting the incident light or absorbing the incident light.

The light reflected by the first low reflection material layer 410 may be transmitted toward the semiconductor layer of each TFT. For example, although the amount of the light reflected by the first low reflection material layer 410 is reduced, the light reflected by the first low reflection material layer 410 may influence the property of the semiconductor layer of the oxide semiconductor material.

To further prevent or at least reduce deterioration of the semiconductor layer due to the light reflected by the first low reflection material layer 410, a top surface (a top layer) of the third source electrode 328S, the third drain electrode 328D, the first source electrode 375S, the first drain electrode 375D, the second source electrode 319S and the second drain electrode 319D may be formed to include a second low reflection material layer 420. The second low reflection material layer 420 may reduce an amount of the reflected light by irregularly or totally reflecting the incident light or absorbing the incident light.

Since an amount of the light reflected by the first low reflection material layer 410 and the second low reflection material layer 420 is reduced, the light incident to the semiconductor layer of each TFT may be reduced. As a result, the influence on the semiconductor layer of the oxide semiconductor material due to the light is reduced and a reliability of the display device 100 is obtained.

The first low reflection material layer 410 and the second low reflection material layer 420 may have a single layer or a multiple layer including one of molybdenum (Mo), titanium (Ti), zirconium (Zr), hafnium (Hf), tantalum (Ta), chromium (Cr), tungsten (W), vanadium (V), niobium (Nb), manganese (Mn), iron (Fe), cobalt (Co), nickel (Ni), copper (Cu), zinc (Zn), silver (Ag), aluminum (Al) and gold (Au) or an alloy thereof.

Consequently, in the display device according to an embodiment of the present disclosure, since the influence on the semiconductor layer of the oxide semiconductor material of the TFT due to the light of the interior and the exterior is reduced, the reliability is improved.

Example embodiments of the present disclosure can also be described as follows:

According to an example embodiment of a present disclosure, a display device includes: a substrate having a display area and a non-display area; an emitting element connected to a gate line and a data line crossing the gate line in the display area, the emitting element including a first electrode, an emitting layer and a second electrode; a first thin film transistor supplying a driving current to the emitting element according to a data voltage of the data line, the first thin film transistor including a first semiconductor layer, a first source electrode and a first drain electrode; a second thin film transistor controlling an operation of the first thin film transistor according to a gate voltage of the gate line, the second thin film transistor including a second semiconductor layer; a third thin film transistor controlling an operation of the first thin film transistor by sensing a threshold voltage of the first thin film transistor, the third thin film transistor including a third semiconductor layer; a third electrode connecting the first drain electrode and the first electrode; and a fourth electrode having a same layer as the third electrode.

In some example embodiments, the first thin film transistor further includes a first upper gate electrode on the first semiconductor layer, the second thin film transistor further includes a second upper gate electrode on the second semiconductor layer, and the third thin film transistor further includes a third upper gate electrode on the third semiconductor layer.

In some example embodiments, a distance between the third semiconductor layer and the third upper gate electrode is greater than a distance between the first semiconductor layer and the first upper gate electrode.

In some example embodiments, a distance between the third semiconductor layer and the third upper gate electrode is greater than a distance between the second semiconductor layer and the second upper gate electrode.

In some example embodiments, the first thin film transistor further includes a first lower gate electrode under the first semiconductor layer, the second thin film transistor further includes a second lower gate electrode under the second semiconductor layer, and the third thin film transistor further includes a third lower gate electrode under the third semiconductor layer.

In some example embodiments, a distance between the second semiconductor layer and the second lower gate electrode is greater than a distance between the first semiconductor layer and the first lower gate electrode.

In some example embodiments, a distance between the third semiconductor layer and the third lower gate electrode is greater than a distance between the first semiconductor layer and the first lower gate electrode.

In some example embodiments, the first semiconductor layer and the second semiconductor layer include an oxide semiconductor material.

In some example embodiments, the third semiconductor layer includes an oxide semiconductor material.

In some example embodiments, the fourth electrode is disposed to be separated from the third electrode, and the fourth electrode is disposed in an entire display area except for a region where the third electrode is disposed.

In some embodiments, the substrate includes a pixel area, the pixel area includes a plurality of thin film transistors, the plurality of thin film transistors includes the thin film transistor, each of the plurality of thin film transistors includes a low reflection layer, and the fourth electrode overlaps the low reflection layer of the plurality of thin film transistors.

In some example embodiments, the third electrode and the fourth electrode include at least two layers.

In some example embodiments, a bottom layer of the third electrode and the fourth electrode includes a low reflection material layer having at least one layer.

In some example embodiments, the second thin film transistor further includes a second source electrode and a second drain electrode, the third thin film transistor further includes a third source electrode and a third drain electrode, and the first to third source electrodes and the first to third drain electrodes have at least two layers.

In some example embodiments, a top layer of the first to third source electrodes and the first to third drain electrodes includes a low reflection material layer having at least one layer.

In some example embodiments, the low reflection material layer has one of a single layer and a multiple layer including one of molybdenum (Mo), titanium (Ti), zirconium (Zr), hafnium (Hf), tantalum (Ta), chromium (Cr), tungsten (W), vanadium (V), niobium (Nb), manganese (Mn), iron (Fe), cobalt (Co), nickel (Ni), copper (Cu), zinc (Zn), silver (Ag), aluminum (Al) and gold (Au) and an alloy thereof.

In some example embodiments, the first source electrode is connected to the first lower gate electrode.

In some example embodiments, the display device further includes: a line part, a dam layer and a gate driving unit in the non-display area; and a fourth thin film transistor in the gate driving unit, the fourth thin film transistor applying the gate voltage to the second thin film transistor and including a fourth semiconductor layer.

In some example embodiments, the fourth semiconductor layer includes a polycrystalline semiconductor material.

In some example embodiments, the display device further includes: an encapsulation part on the emitting element, the encapsulation part including a first encapsulating layer, a second encapsulating layer and a third encapsulating layer; and a touch part on the encapsulation part.

In some example embodiments, the display device further includes a color filter layer on one of the encapsulation part and the touch part.

It will be apparent to those skilled in the art that various modifications and variation can be made in the present disclosure without departing from the scope of the disclosure. Thus, it is intended that the present disclosure cover the modifications and variations of this disclosure, provided they come within the scope of the appended claims and their equivalents.

What is claimed is:

1. A display device, comprising:
a substrate having a display area and a non-display area;
an emitting element connected to a gate line and a data line crossing the gate line in the display area, the emitting element including a first electrode, an emitting layer and a second electrode;
a first thin film transistor supplying a driving current to the emitting element according to a data voltage of the data line, the first thin film transistor including a first semiconductor layer, a first source electrode and a first drain electrode;
a second thin film transistor controlling an operation of the first thin film transistor according to a gate voltage of the gate line, the second thin film transistor including a second semiconductor layer;
a third thin film transistor controlling an operation of the first thin film transistor by sensing a threshold voltage of the first thin film transistor, the third thin film transistor including a third semiconductor layer;
a third electrode electrically connecting the first drain electrode and the first electrode; and
a fourth electrode on a same layer as the third electrode.

2. The display device of claim 1, wherein the first thin film transistor further includes a first upper gate electrode on the first semiconductor layer,
wherein the second thin film transistor further includes a second upper gate electrode on the second semiconductor layer, and
wherein the third thin film transistor further includes a third upper gate electrode on the third semiconductor layer.

3. The display device of claim 2, wherein a distance between the third semiconductor layer and the third upper gate electrode is greater than a distance between the first semiconductor layer and the first upper gate electrode, and
wherein a distance between the third semiconductor layer and the third upper gate electrode is greater than a distance between the second semiconductor layer and the second upper gate electrode.

4. The display device of claim 2, wherein the first thin film transistor further includes a first lower gate electrode under the first semiconductor layer,
wherein the second thin film transistor further includes a second lower gate electrode under the second semiconductor layer, and
wherein the third thin film transistor further includes a third lower gate electrode under the third semiconductor layer.

5. The display device of claim 4, wherein a distance between the second semiconductor layer and the second lower gate electrode is greater than a distance between the first semiconductor layer and the first lower gate electrode, and
wherein a distance between the third semiconductor layer and the third lower gate electrode is greater than a distance between the first semiconductor layer and the first lower gate electrode.

6. The display device of claim 1, wherein at least one of the first semiconductor layer, the second semiconductor layer, or the third semiconductor layer includes an oxide semiconductor material.

7. The display device of claim 1, wherein the third semiconductor layer includes an oxide semiconductor material.

8. The display device of claim 1, wherein the fourth electrode is separated from the third electrode, and
wherein the fourth electrode extends across an entire display area, excluding a region where the third electrode resides and a gap between the third electrode and the fourth electrode.

9. The display device of claim 1, wherein the third electrode or the fourth electrode includes a plurality of layers.

10. The display device of claim 9, wherein a bottom layer of the plurality of layers includes a low reflection material.

11. The display device of claim 4, wherein the second thin film transistor further includes a second source electrode and a second drain electrode,
wherein the third thin film transistor further includes a third source electrode and a third drain electrode, and
wherein the first source electrode, the second source electrode, the third source electrode, the first drain electrode, the second drain electrode, or the third drain electrode comprises a plurality of layers.

12. The display device of claim 11, wherein a top layer of the plurality of layers includes a low reflection material.

13. The display device of claim 12, wherein the low reflection material comprises at least one of molybdenum (Mo), titanium (Ti), zirconium (Zr), hafnium (Hf), tantalum (Ta), chromium (Cr), tungsten (W), vanadium (V), niobium (Nb), manganese (Mn), iron (Fe), cobalt (Co), nickel (Ni), copper (Cu), zinc (Zn), silver (Ag), aluminum (Al) and gold (Au) and an alloy thereof.

14. The display device of claim 11, wherein the first source electrode is electrically connected to the first lower gate electrode.

15. The display device of claim 1, further comprising:
a line part, a dam layer and a gate driving unit in the non-display area; and
a fourth thin film transistor in the gate driving unit, the fourth thin film transistor applying the gate voltage to the second thin film transistor and including a fourth semiconductor layer.

16. The display device of claim 15, wherein the fourth semiconductor layer includes a polycrystalline semiconductor material.

17. The display device of claim 1, further comprising:
an encapsulation part on the emitting element, the encapsulation part including a first encapsulating layer, a second encapsulating layer and a third encapsulating layer; and
a touch part on the encapsulation part.

18. A display device, comprising:
a substrate;
a thin film transistor on the substrate, the thin film transistor including:
a semiconductor layer including oxide semiconductor, and
a source electrode and a drain electrode, the source electrode and drain electrode above the semiconductor layer;
a light emitting element on the thin film transistor, wherein the light emitting element includes a first electrode, an emitting layer, and a second electrode;
a third electrode between the thin film transistor and the light emitting element on a planarizing layer, wherein the third electrode electrically connects the first electrode to one of the source electrode or the drain electrode of the thin film transistor; and
a fourth electrode on the planarizing layer, wherein the fourth electrode overlaps the semiconductor layer in a first direction, and at least a portion of the fourth electrode is spaced apart from the third electrode.

19. The display device of claim 18, wherein the fourth electrode is configured to block at least a portion of light incident to the fourth electrode from reaching the semiconductor layer.

20. The display device of claim 18, wherein the fourth electrode includes a plurality of layers, and a bottom layer of the plurality of layers is a low reflection material layer configured to absorb at least a portion of light reflected to the low reflection material layer.

21. The display device of claim 18, wherein the third electrode includes a plurality of layers, and a bottom layer of the plurality of layers is a low reflection material layer configured to absorb at least a portion of light reflected to the low reflection material layer.

22. The display device of claim 18, wherein the source electrode or the drain electrode includes a plurality of layers, a top layer of the plurality of layers is a low reflection material layer configured to absorb at least a portion of light reflected from a bottom surface of the fourth electrode to the low reflection material layer.

23. The display device of claim 20, wherein the low reflection material layer comprises at least one of molybdenum (Mo), titanium (Ti), zirconium (Zr), hafnium (Hf), tantalum (Ta), chromium (Cr), tungsten (W), vanadium (V), niobium (Nb), manganese (Mn), iron (Fe), cobalt (Co), nickel (Ni), copper (Cu), zinc (Zn), silver (Ag), aluminum (Al) and gold (Au) and an alloy thereof.

24. The display device of claim 18, wherein the substrate includes a pixel area, the pixel area includes a plurality of thin film transistors, the plurality of thin film transistors including the thin film transistor, each of the plurality of thin film transistors includes a semiconductor layer including oxide semiconductor, and the fourth electrode extends across to overlap the semiconductor layers of the plurality of thin film transistors.
